(19) United States
(12) Patent Application Publication
(10) Pub. No.: US 2024/0297482 A1
(43) Pub. Date: Sep. 5, 2024

(54) LASER MODULE AND METHOD FOR MANUFACTURING THE SAME

(71) Applicant: NATIONAL SUN YAT-SEN UNIVERSITY, Kaohsiung City (TW)

(72) Inventors: PO-HONG CHEN, Kaohsiung City (TW); YI-JEN CHIU, Kaohsiung City (TW); KUAN-YU CHEN, Kaohsiung City (TW); CHUNG-WEI HSIAO, Kaohsiung City (TW)

(21) Appl. No.: 18/531,762

(22) Filed: Dec. 7, 2023

(30) Foreign Application Priority Data
Mar. 1, 2023 (TW) 112107343

(51) Int. Cl. H01S 5/12; H01S 5/028; H01S 5/24; H01S 5/343

(52) U.S. Cl. CPC H01S 5/12; H01S 5/028; H01S 5/24; H01S 5/3434

(57) ABSTRACT

A laser module includes a substrate, a laser unit, an optical amplification unit, a high reflection layer and a low reflection layer. The laser unit is disposed on the substrate and configured to generate a laser light. The optical amplification unit is disposed on the substrate. An optical channel of the optical amplification unit is communicated with an optical channel of the laser unit. An electrode of the optical amplification unit is electrically isolated from an electrode of the laser unit. The high reflection layer is disposed on an end of the laser unit away from the optical amplification unit. The low reflection layer is disposed on an end of the optical amplification unit away from the laser unit. The laser light and a gain light are emitted to an outside of the laser module via the low reflection layer. A method for manufacturing the laser module is also provided.

### CROSS REFERENCE TO RELATED APPLICATION

The application claims the benefit of Taiwan application serial No. 112107343, filed on Mar. 1, 2023, and the entire contents of which are incorporated herein by reference.

### BACKGROUND OF THE INVENTION

### 1. Field of the Invention

The present invention relates to a laser module and, more particularly, to a laser module with a laser unit and an optical amplification unit.

### 2. Description of the Related Art

In recent years, the development of laser, which is crucial for next-generation optical network applications, has increasingly required higher bandwidth, making it difficult for conventional lasers and laser modules to meet the criteria of next-generation optical network applications.

For example, the response frequency of a conventional direct modulated laser is usually limited to about 30 GHz. However, the method for changing the amplitude or phase of a continuously output laser light source using indirect modulated laser is more complicated than the direct modulated laser. In addition, the semiconductor structures of directly modulated lasers and indirectly modulated lasers often require repeated epitaxy, resulting in high process difficulty and high cost.

In light of the above, it is necessary to improve conventional techniques of semiconductor laser.

### SUMMARY OF THE INVENTION

To solve the above problem, it is an objective of the present invention to provide a laser module having a laser unit and an optical amplification unit to improve the laser response frequency and reduce the difficulty and cost of the manufacturing process.

As used herein, the term “a”, “an” or “one” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

A laser module according to the present invention includes a substrate, a laser unit, an optical amplification unit, a high reflection layer and a low reflection layer. The laser unit is disposed on the substrate and configured to generate a laser light. The optical amplification unit is disposed on the substrate. An optical channel of the optical amplification unit is communicated with an optical channel of the laser unit, and an electrode of the optical amplification unit is electrically isolated from an electrode of the laser unit. The high reflection layer is disposed on an end of the laser unit oriented away from the optical amplification unit. The low reflection layer is disposed on an end of the optical amplification unit oriented away from the laser unit. The reflectance of the low reflection layer is fine tunable. A gain light is produced by entering the laser light emitted from the optical channel of the laser unit into the optical channel of the optical amplification unit, such that electrons in the optical channel of the optical amplification unit that have energy higher than a ground state are induced to return to the ground state, and fine tuning the reflectance of the low reflection layer to cause a reflected light of the optical amplification unit to induce a photon-photon resonance effect with the laser light of the laser unit. The laser light and the gain light are emitted to an outside of the laser module via the low reflection layer.

A method for manufacturing a laser module includes: growing an InGaAsP material on an InP substrate, with the InGaAsP material forming a grating and subsequently growing a quantum well structure and a cladding layer, with the quantum well structure including active layers of a laser unit and an optical amplification unit; forming a trench along an X-axis direction by performing a dry etching process toward a −Z direction to a predetermined depth, and then performing a wet etching method toward +Y and −Y directions to form angled sidewalls, such that a cross-section of the trench is an inverted trapezoid, with optical channels of the laser unit and the optical amplification unit disposed in the trench; removing a contact layer between the laser unit and the optical amplification unit and disposing a planarized layer on both sides of the active layer and over the cladding layer; and depositing a P-type electrode and a N-type electrode, and disposing a high reflection layer close to the laser unit and a low reflection layer close to the optical amplification unit.

Accordingly, the laser module and the method for forming the same of the present invention can effectively widen the bandwidth of the frequency response and improve the efficiency of the output power by combining the laser unit and the optical amplification unit.

In an example, the laser module of the present invention further includes a trench extending from the high reflection layer to the low reflection layer. The optical channel of the optical amplification unit and the optical channel of the laser unit are disposed in the trench to form an optical waveguide. Thus, optical waveguide materials, semiconductors and metal materials can be deposited and etched inside and outside the trench, thereby simplifying the manufacturing process and reducing costs.

In an example, a cross-sectional shape of the trench is an inverted trapezoid. Thus, the optical waveguide located in the trench forms a reverse ridge waveguide, which can reduce the parasitic capacitance and contact resistance of the laser module and improve the high-frequency response, such that the components of the laser module can achieve high-speed functions easily.

In an example, the laser unit is a distributed feedback Bragg grating laser, and the optical amplification unit is a semiconductor optical amplification. Thus, by using a distributed feedback Bragg grating laser, the number of photon oscillations in the cavity can be increased to provide gain, and excess modes can be suppressed to allow the laser to operate in a single mode.

In an example, a planarized layer of at least one of the laser unit and the optical amplification unit is made of benzocyclobutene. Thus, by using a planarized layer made of benzocyclobutene material, the effect of reducing the parasitic capacitance of at least one of the laser unit and the optical amplification unit can be achieved.

In an example, the sidewalls of the trench are formed by etching using an acid-base complex. Thus, angled sidewalls can be formed in the trench, thereby achieving the effect of disposing an reverse ridge waveguide.

In an example, the predetermined depth of the trench is 0.8 μm, and the length of a lower base of the inverted trapezoid is 3 μm. Thus, a reverse ridge waveguide can be disposed, thereby achieving the effect of reducing parasitic capacitance and contact resistance and improving high-frequency response.

In an example, the contact layer between the optical amplification unit and the laser unit is removed by a solution containing sulfuric acid, hydrogen peroxide and water. Thus, the effect of avoiding crosstalk between signals can be achieved.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 illustrates a cross-sectional view of laminated layers of a preferred embodiment of the present invention.

FIG. 2 illustrates a cross-sectional view along the line 2-2 in FIG. 1.

FIG. 3 illustrates a systematic block diagram of the laser module of the present invention while performing a microwave penetration loss measurement.

FIG. 4 is the frequency response diagram of a common DFB laser.

FIG. 5 is the frequency response diagram of the laser module of the present invention

As used herein, directionality or similar terms, such as “front,” “back,” “left,” “right,” “upper (top),” “lower (bottom),” “inner,”, “outer,” “side,” etc. mainly refer to the directions of the attached drawings. Each directionality or its approximate terms are only used to assist in explaining and understanding the various embodiments of the present invention, and are not intended to limit the present invention.

### DETAILED DESCRIPTION OF THE INVENTION

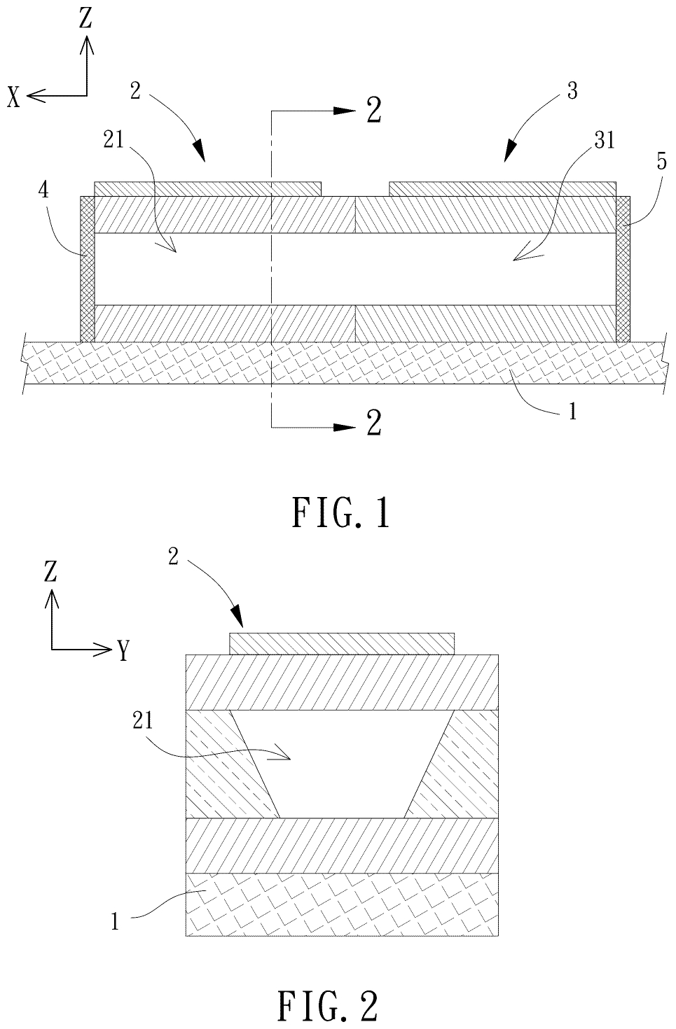

FIG. 1 is a side cross-sectional view of an embodiment of a laser module of the present invention. The laser module includes a substrate 1, a laser unit 2, an optical amplification unit 3, a high reflection layer 4 and a low reflection layer 5. The laser unit 2 and the optical amplification unit 3 are disposed on the substrate 1, the high reflection layer 4 is disposed on an end of the laser unit 2 oriented away from the optical amplification unit 3, and the low reflection layer 5 is disposed on an end of the optical amplification unit 3 oriented away from the laser unit 2. An optical channel 31 of the optical amplification unit 3 is communicated with an optical channel 21 of the laser unit 2.

It is noted that the geometric relationships between the components of the laser module in FIG. 1 are described using the Cartesian coordinate system.

In an embodiment, the laser unit 2 is a distributed feedback Bragg grating laser (DFB laser), and the optical amplification unit 3 is a semiconductor optical amplification (SOA). Therefore, the laser light emitted from the optical channel 21 of the laser unit 2 enters the optical channel 31 of the optical amplification unit 3, such that the electrons in the optical channel 31 of the optical amplification unit 3 that have energy higher than the ground state to be induced to return to the ground state to produce a gain light. Then, the laser light and the gain light are emitted to the outside of the laser module via the low reflection layer 5.

The material of the substrate 1 can be selected as needed. For example, the substrate 1 can be made of III-V semiconductor materials. In this example, the material of the substrate 1 can be indium phosphide (InP). However, II-VI semiconductor materials may also be used as the material of the substrate 1 if necessary, and the material, structure, and location of other components of the laser module, such as a N-cladding layer, P-cladding layer, active layer, passivation layer, etc. can be modified accordingly. Accordingly, for example, a planarized layer, the high reflection layer 4, the low reflection layer 5, etc. can be modified based on the optical characteristics caused by the material, structure, and location of the above components, without departing from the spirit of the present invention.

As shown in FIGS. 1 and 2, in an embodiment, the laser module of the present invention can be provided with a trench. The trench extends along the X-axis direction to connect at least the optical channel 31 of the optical amplification unit 3 and the optical channel 21 of the laser unit 2 to form an optical waveguide in the trench.

Preferably, the shape of the trench orthographically projected on the high reflection layer 4 and the low reflection layer 5 is a trapezoid. The length of the upper base of the trapezoid is greater than the length of the lower base of the trapezoid, and the two bases are aligned with the surface of the laser module. Specifically, the cross-sectional shape of the trench in the Y-Z plane may be an inverted trapezoid with a longer upper base and a shorter lower base. The inverted trapezoid extends toward the X-axis direction to form the trench with a columnar shape, such that the optical waveguide is a reversed ridge waveguide embedded in the substrate 1.

As shown in FIG. 2, taking the cross-section of the laser unit 2 in the Y-Z plane as an example, the length of the lower base of the inverted trapezoid toward the +Z direction is greater than the length of the lower base of the inverted trapezoid toward the −Z direction. Moreover, the trapezoid is the cross-sectional shape of the optical channel 21 of the laser unit 2.

Optionally, the optical waveguide can be manufactured as follows: defining a bottom profile of the optical waveguide on the substrate 1 (such as patterned silicon dioxide, SiO₂); etching the substrate 1 toward the —Z direction to a predetermined depth (such as 0.8 μm) using a dry etching method (such as inductively coupled plasma, ICP); and etching side walls of the trench toward the +Y and −Y directions respectively by wet etching, such that the cross-section of the trench is an inverted trapezoid. In an embodiment, the wet etching can be performed using A: B acid, i.e., an acid-base complex. In an example, the length of the lower base of the trapezoid is 3 μm.

Accordingly, the reverse ridge waveguide can not only reduce the parasitic capacitance and the contact resistance of the laser module, but also improve the high-frequency response, such that the components of the laser module can reach high speeds easily.

In an aspect of the substrate 1, the substrate 1 can be formed by using chemical plating and then grinding the wafer to 100 μm, thereby increasing the heat dissipation of the laser module.

In an embodiment, the structure of the N-cladding layer and the N-cladding layer side electrode of the laser unit 2 and the optical amplification unit 3 includes laminated layers of gold/germanium/nickel/gold/titanium/platinum/gold, and the thickness of which are 300 nm, 200 nm, 500 nm, 500 nm, 500 nm, 500 nm, and 3000 nm, respectively. The structure of the P-cladding layer and the P-cladding layer side electrode includes laminated layers of titanium/platinum/gold, and the thickness of which are 500 nm, 500 nm, and 5000 nm, respectively. After the N-type cladding layer and the N-type cladding layer side electrode are formed, an ohmic contact between the metal layer and the semiconductor can be formed by performing annealing. This is also applicable after the P-type cladding layer and the P-type cladding layer side electrode are formed.

In an embodiment, an insulating region is formed between the laser unit 2 and the optical amplification unit 3 by etching the bottom of the trench. The insulating region extends along the Y-axis to separate at least the laser unit 2 and the optical amplification unit 3. In an example, the insulating region may form a passivation layer, and the material of the passivation layer may be an oxide. Additionally, at least the N-cladding layer side electrode or the P-cladding layer side electrode can be separated by the insulating region, such that the electrode of the optical amplification unit 3 and the electrode of the laser unit 2 are electrically isolated. Furthermore, the materials of each layer in the N-cladding layer and the N-cladding layer side electrode of the laser unit 2 and the optical amplification unit 3 can be formed together, and the materials of each layer in the P-cladding layers and the P-cladding layer side electrode of the laser unit 2 and the optical amplification unit 3 can be formed together, thereby simplifying the manufacturing process and reducing costs. The length of the insulating region along the X-axis is 70 μm.

The active layer of the laser unit 2 and the optical amplification unit 3 can be a multiple quantum well, and the material and structure of the multiple quantum well can be adjusted according to the required wavelength, substrate, etc. In this embodiment, the length of the active layer of the laser unit 2 along the X-axis is 150 μm, and the length of the active layer of the optical amplification unit 3 along the X-axis is 150 μm. By controlling the bias current of the optical amplification unit 3 to be fixed at 15 mA and adjusting the bias current of the laser unit 2 from 20 mA to 70 mA, a laser light with wavelengths from 1328.5 nm to 1330 nm and the gain light thereof can be output.

However, the arrangement of each layer of the N-cladding layer, N-cladding layer side electrode, P-cladding layer, and P-cladding layer side electrode may be adjusted depending on the active layer structure, the substrate 1 and the like. For example, in a case where the N-cladding layer and the N-cladding layer side electrode are positioned close to the bottom of the trench, the structure of the N-cladding layer and the N-cladding layer side electrode is AuGe/Ni/Au/Ti/Pt/Au arranged toward the −Z direction, and the structure of the P-cladding layer and the P-cladding layer side electrode is Ti/Pt/Au arranged toward the +Z direction. In a case where the P-cladding layer and the P-cladding layer side electrode are positioned close to the bottom of the trench, the structure of the P-cladding layer and the P-cladding layer side electrode is Ti/Pt/Au arranged toward the −Z direction, and the structure of the N-cladding layer and the N-cladding layer side electrode is AuGe/Ni/Au/Ti/Pt/Au arranged toward the +Z direction.

In an embodiment with respect to an aspect of the P-cladding layer and the P-cladding layer side electrode, after plating silicon nitride (SiNx) using plasma-enhanced chemical vapor deposition (PECVD), ICP is used to dry-etch until the contact layer InGaAs is exposed. Then, an electron gun (E-gun) is used to perform the evaporative deposition of the P-cladding layer and the P-cladding layer side electrode.

In an embodiment, the grating of the laser unit 2 is formed by using indium gallium arsenide phosphide (InGaAsP) as the grating material to grow on an indium phosphide (InP) substrate using a metal organic chemical vapor deposition (MOCVD) method, and defining the grating in a specific area using a photoresist for electron beam and an electron beam writer (E-beam writer) and etching the area to a specific thickness to form the grating.

The planarized layer of at least one of the laser unit 2 and the optical amplification unit 3 is made of benzocyclobutene (BCB). In an example, the planarized layer is disposed on both sides of the active layer and over the cladding layers. The parasitic capacitance of at least one of the laser unit 2 and the optical amplification unit 3 can be reduced by the planarized layer made of benzocyclobutene.

In the embodiment with respect to an aspect of an adjacent area between the laser unit 2 and the optical amplification unit 3, a contact layer of the adjacent area between the laser unit 2 and the optical amplification unit 3 is removed by a solution containing sulfuric acid, hydrogen peroxide and water to avoid crosstalk between signals.

The low reflection layer 5 is configured to control the output direction of the laser light and the gain light, and reduce reflection to increase the light output power. By fine-tuning the reflectivity of the low reflection layer 5, the reflected light of the optical amplification unit 3 can induce a photon-photon resonance effect with the laser light of the laser unit 2, thereby improving the bandwidth of the laser light.

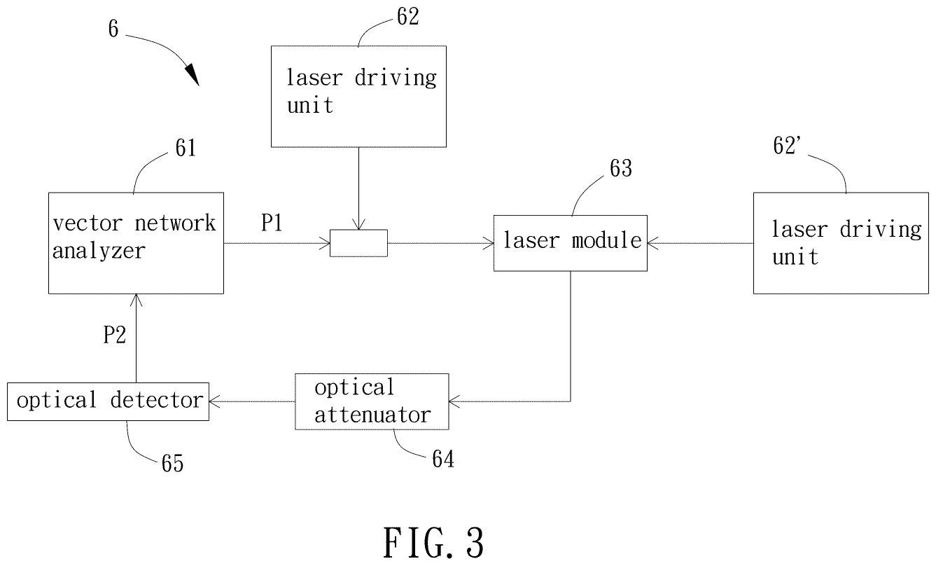

FIG. 3 is a block diagram of a measurement system 6 for measuring microwave penetration loss using the laser module of the present invention. As shown in FIG. 3, a microwave signal is sent from a port P1 by a vector network analyzer (VNA) 61 and is subsequently mixed with a DC signal outputted by a laser driving unit 62 of a laser diode driver in a constant current mode through a bias tee, thereby driving the optical amplification unit of the laser module 63 of the present invention. Another laser driving unit 62′ provides an AC signal to drive the laser unit of the laser module 63, thereby causing the laser module 63 to generate a laser light. The laser light is coupled using a tapered optical fiber, and an optical attenuator 64 is used to reduce the output power to a power suitable for an optical detector 65. Finally, the optical detector 65 converts the received optical signal into an electric signal and return it from a port P2 to the vector network analyzer 61 to analyze the response frequency of the laser. This can modulate the bias current of the optical amplification unit of the laser module 63 driven by the laser driving unit 62 by fine-tuning the microwave signal.

The reason and details of this measurement are that when transmitting microwave signals, the signals may be attenuated due to obstacles or other factors. This loss may cause the signal to weaken or even disappear completely within a certain distance. The degree of microwave loss may be affected by many factors, including transmission distance, transmission frequency, transmission power, material and density of obstacles, etc. Generally, components suffer greater losses when transmitting high-frequency signals. Therefore, the frequency at which the received intensity is half the output intensity is defined as the frequency response of the component. Frequency response refers to the output response of a system with respect to input signals of different frequencies. Frequency response can be used to indicate the sensitivity of a system with respect to signals of different frequencies, and can also be used to measure the frequency characteristics of the system. Therefore, it is necessary to analyze the microwave loss of the components. Microwave loss can be divided into two types, namely, microwave reflection loss and microwave transmission loss. Microwave reflection loss may usually be reduced by impedance matching to reduce signal reflectivity. Microwave transmission loss refers to the loss caused by microwave transmission within the component. Generally speaking, the longer the component length, the greater the loss.

The steps for this measurement are that first fixing the bias current of the laser unit and changing the bias current of the optical amplification unit to observe the change in frequency response. Then, fixing the bias current of the optical amplification unit and changing the bias current of the laser unit. After this measurement, the suitable bias currents for the laser unit and the optical amplification unit for inducing the photon-photon resonance effect can be found.

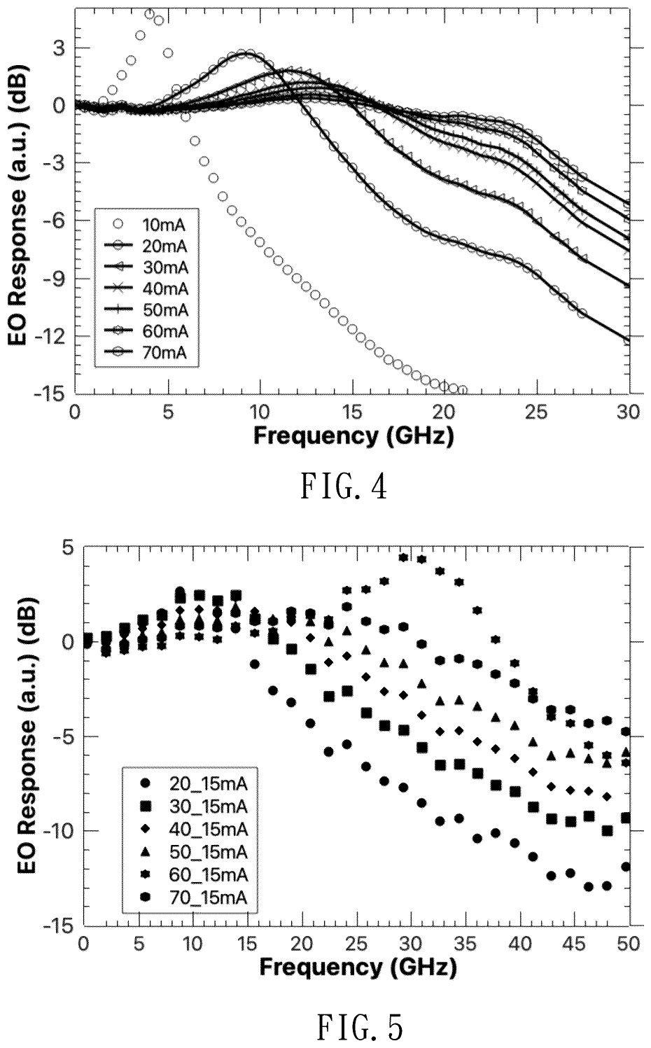

Now refer to FIGS. 4 and 5. FIG. 4 is the frequency response diagram of a common DFB laser, and FIG. 5 is the frequency response diagram of the laser module of the present invention. As shown, the bandwidth of the frequency response at f3 dB (frequency range greater than-3 dB) widens from 28 GHz (where the bandwidth is 9 GHz when the DFB bias current is 10 mA, and is 28 GHz when the DFB bias current is above 60 mA) to 40 GHz (where the bandwidth is 40 GHz when the bias current of the laser module of the present application is above 60 mA)

In summary, the laser module and the method for forming the same of the present invention can effectively widen the bandwidth of the frequency response by combining the laser unit and the optical amplification unit. Moreover, a reverse ridge waveguide can reduce the parasitic capacitance and contact resistance of the laser module and improve the high-frequency response, such that the components of the laser module can achieve high-speed functions easily. In addition, each component of the laser unit and the optical amplification unit with the same semiconductor, metal, and polymer materials can be formed together, thereby simplifying the manufacturing process and reducing costs. A planarized layer made of benzocyclobutene material can reduce the parasitic capacitance of at least one of the laser unit and the optical amplification unit. Finally, the effect of avoiding crosstalk between signals can be achieved by removing a contact layer of the adjacent area between the laser unit and the optical amplification unit using a solution containing sulfuric acid, hydrogen peroxide and water.

Although the present invention has been described with respect to the above preferred embodiments, these embodiments are not intended to restrict the present invention. Various changes and modifications on the above embodiments made by any person skilled in the art without departing from the spirit and scope of the present invention are still within the technical category protected by the present invention. Accordingly, the scope of the present invention shall include the literal meaning set forth in the appended claims and all changes which come within the range of equivalency of the claims. Further, if the above mentioned several embodiments can be combined, the present invention includes any implementation aspects of combinations thereof.

What is claimed is:

1. A laser module, comprising:
a substrate;
a laser unit disposed on the substrate and configured to generate a laser light;
an optical amplification unit disposed on the substrate, wherein an optical channel of the optical amplification unit is communicated with an optical channel of the laser unit, and an electrode of the optical amplification unit is electrically isolated from an electrode of the laser unit;
a high reflection layer disposed on an end of the laser unit oriented away from the optical amplification unit; and
a low reflection layer disposed on an end of the optical amplification unit oriented away from the laser unit, wherein a reflectance of the low reflection layer is fine tunable,
wherein a gain light is produced by entering the laser light emitted from the optical channel of the laser unit into the optical channel of the optical amplification unit, such that electrons in the optical channel of the optical amplification unit that have energy higher than a ground state are induced to return to the ground state, and fine tuning the reflectance of the low reflection layer to cause a reflected light of the optical amplification unit to induce a photon-photon resonance effect with the laser light of the laser unit, and
wherein the laser light and the gain light are emitted to an outside of the laser module via the low reflection layer.

2. The laser module as claimed in claim 1, further comprising a trench extending from the high reflection layer to the low reflection layer, wherein the optical channel of the optical amplification unit and the optical channel of the laser unit are disposed in the trench to form an optical waveguide.

3. The laser module as claimed in claim 2, wherein a cross-sectional shape of the trench is an inverted trapezoid.

4. The laser module as claimed in claim 1, wherein the laser unit is a distributed feedback Bragg grating laser, and the optical amplification unit is a semiconductor optical amplification.

5. The laser module as claimed in claim 1, wherein a planarized layer of at least one of the laser unit and the optical amplification unit is made of benzocyclobutene.

6. A method for manufacturing a laser module, comprising:
growing an InGaAsP material on an InP substrate, wherein the InGaAsP material forms a grating and subsequently grows a quantum well structure and a cladding layer, wherein the quantum well structure includes active layers of a laser unit and an optical amplification unit;
forming a trench along an X-axis direction by performing a dry etching process toward a −Z direction to a predetermined depth, and then performing a wet etching method toward +Y and −Y directions to form angled sidewalls, such that a cross-section of the trench is an inverted trapezoid, wherein optical channels of the laser unit and the optical amplification unit are disposed in the trench;
removing a contact layer between the laser unit and the optical amplification unit and disposing a planarized layer on both sides of the active layer and over the cladding layer; and
depositing a P-type electrode and a N-type electrode, and disposing a high reflection layer close to the laser unit and a low reflection layer close to the optical amplification unit.

7. The method for manufacturing the laser module as claimed in claim 6, wherein the sidewalls of the trench are formed by etching using an acid-base complex.

8. The method for manufacturing the laser module as claimed in claim 6, wherein the predetermined depth of the trench is 0.8 μm, and the length of a lower base of the inverted trapezoid is 3 μm.

9. The method for manufacturing the laser module as claimed in claim 6, wherein the contact layer between the optical amplification unit and the laser unit is removed by a solution containing sulfuric acid, hydrogen peroxide and water.
